(19) United States
(12) Patent Application Publication
(10) Pub. No.: US 2009/0014705 A1
(43) Pub. Date: Jan. 15, 2009

(54) PHASE CHANGE MEMORY DEVICE AND METHOD FOR FABRICATING THE SAME

(75) Inventors: Hong-Hui Hsu, Changhua County (TW); Frederick T. Chen, Hsinchu (TW); Ming-Jer Kao, Tainan City (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 12/127,712

(22) Filed: May 27, 2008

(30) Foreign Application Priority Data
Jul. 9, 2007 (TW) TW96124890

(51) Int. Cl. H01L 29/04; H01L 21/77

(52) U.S. Cl. 257/3; 365/163; 257/4; 257/5; 257/200; 438/55; 438/467; 438/597; 438/900; 257/E29.003; 257/E21.598

(57) ABSTRACT

A phase change memory device is provided. The phase change memory device comprises a substrate. A first conductive layer is formed on the substrate. A heating electrode is formed on the first conductive layer, and electrically connected to the first conductive layer, wherein the heating electrode comprises a carbon nanotube (CNT). A phase change material layer covers the heating electrode. A second conductive layer is formed on the phase change material layer, and electrically connected to the phase change material layer.

### BACKGROUND OF THE INVENTION

1. Field of the Invention

The invention relates to a phase change memory device and method for fabricating the same, and more particularly to a phase change memory device with a smaller contact area and a relatively higher device density and a method for fabricating the same.

2. Description of the Related Art

Phase change memory (PCM) devices are the most promising devices to replace current non-volatile memory devices. Advantages of PCMs include non-volatile memory characteristics, faster operating speeds, simpler fabrication processes and integration compatibility with conventional semiconductor fabrication. A recent trend in PCM technology is to reduce device operating current. Therefore, a contact area between a phase change material layer and a heating electrode is continually being minimized. In addition, volume is also being minimized. When minimizing the heating electrode volume, however, an electromigration problem occurs due to excessive local current density induced by the heating electrode. Thus, suitable materials for the heating electrode which can withstand high current density and offer good thermal stability are desired.

To solve the aforementioned problem, H. Tanaka et. al (reported in Jpn. J. Appl. Phys, 2002) discloses a conventional PCM heating electrode formed as rhodium (Rh) nanometer-scale lines by depositing rhodium in a nanometer-scale hole using an electroplating method. If some local Rh nanometer-scale lines transform too slowly when reaching a phase change material layer, or some other local Rh nanometer-scale lines transform too fast to result in an excessive contact area, a non-uniform transformation speed of the rhodium (Rh) nanometer-scale lines occurs. This conventional PCM heating electrode results in a problem of a non-uniform contact area between a phase change material layer and a heating electrode.

A PCM device with a smaller contact area, a relatively higher device density and without electromigration is desired.

### BRIEF SUMMARY OF INVENTION

The invention provides a phase change memory device and method for fabricating the same. An exemplary embodiment of a phase change memory device comprises a substrate, a first conductive layer on the substrate, a heating electrode on and electrically connected to the first conductive layer, wherein the heating electrode comprises a carbon nanotube (CNT), a phase change material layer on and covering the heating electrode, and a second conductive layer on and electrically connected to the phase change material layer.

A method of fabricating a phase change memory device comprises providing a substrate having a first conductive layer thereon, forming a heating electrode on and electrically connected to the first conductive layer, wherein the heating electrode comprises a carbon nanotube (CNT), forming a phase change material layer on and covering the heating electrode, and forming a second conductive layer on and electrically connected to the phase change material layer.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1a to 1h show cross sections of an exemplary embodiment of a phase change memory device of the invention.

FIGS. 2a to 2h show cross sections of another exemplary embodiment of a phase change memory device of the invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

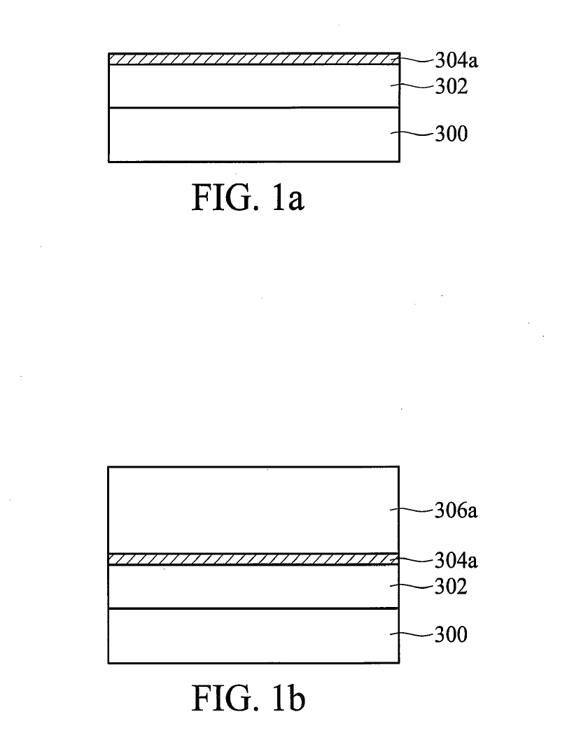

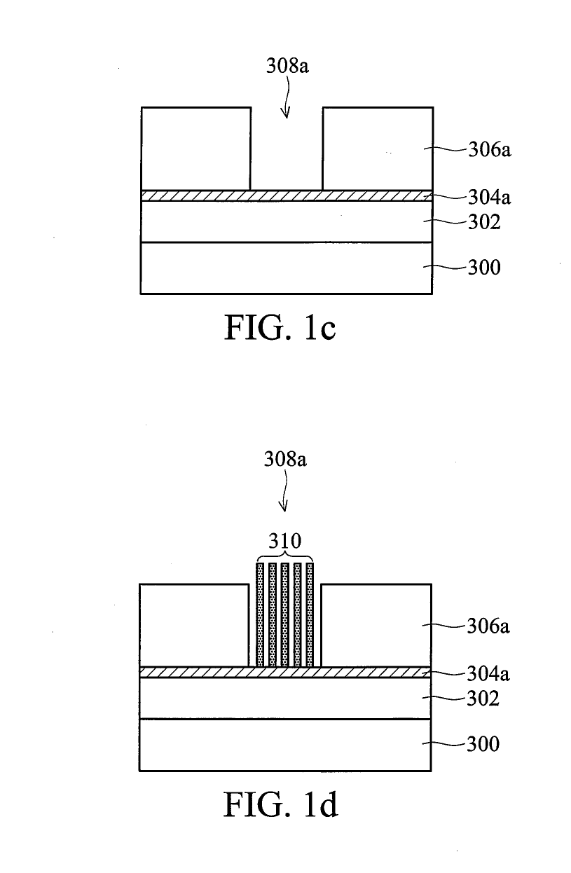

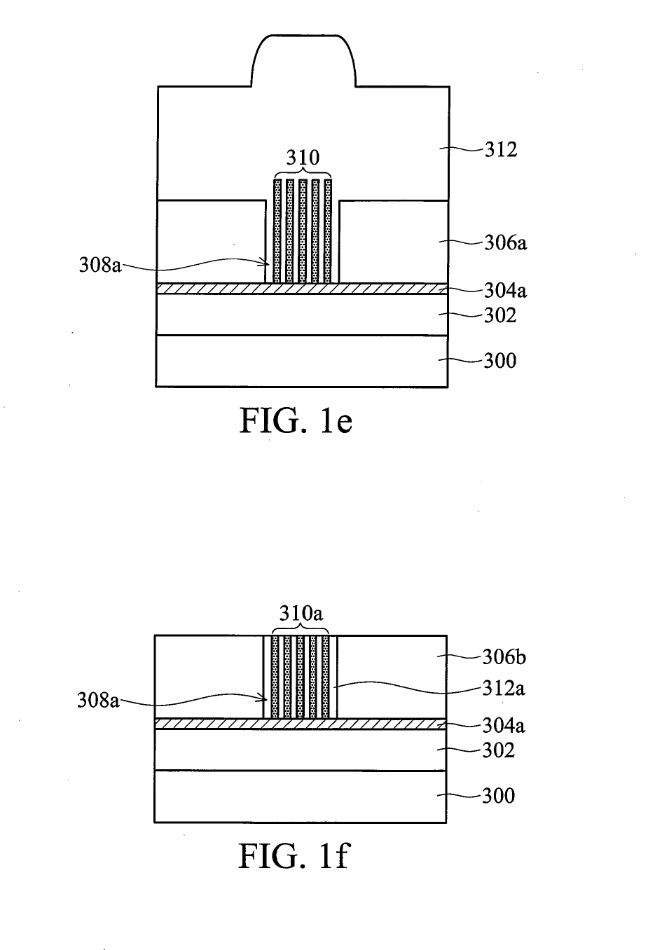

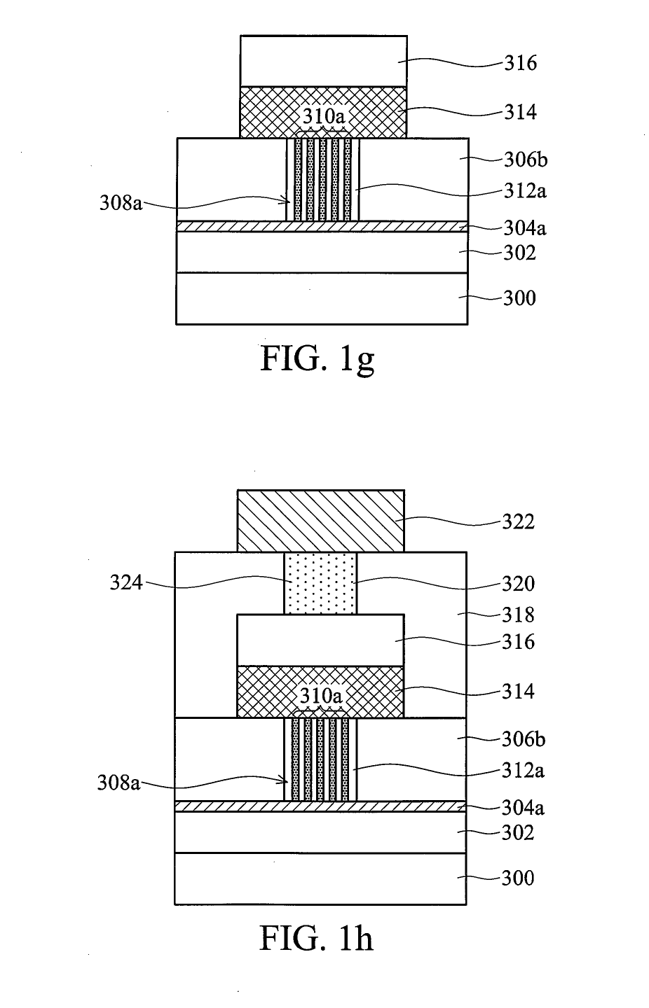

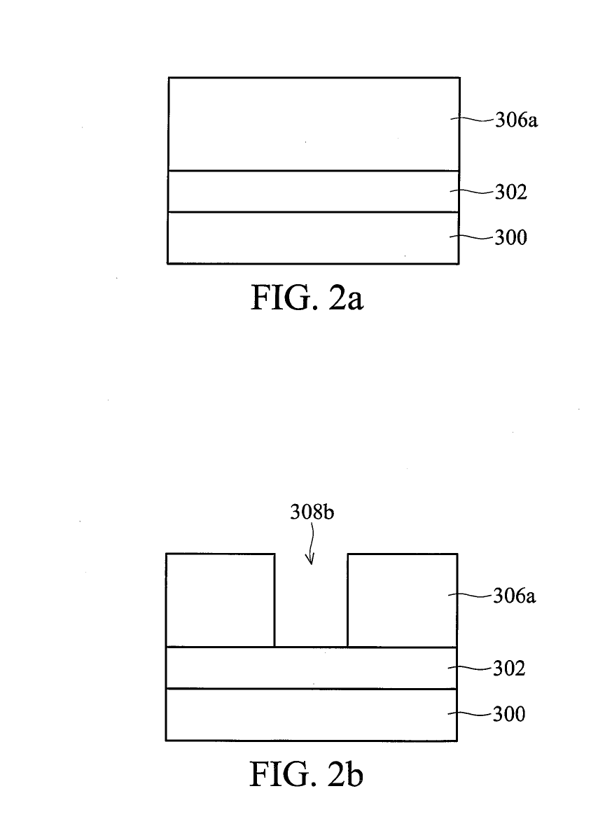

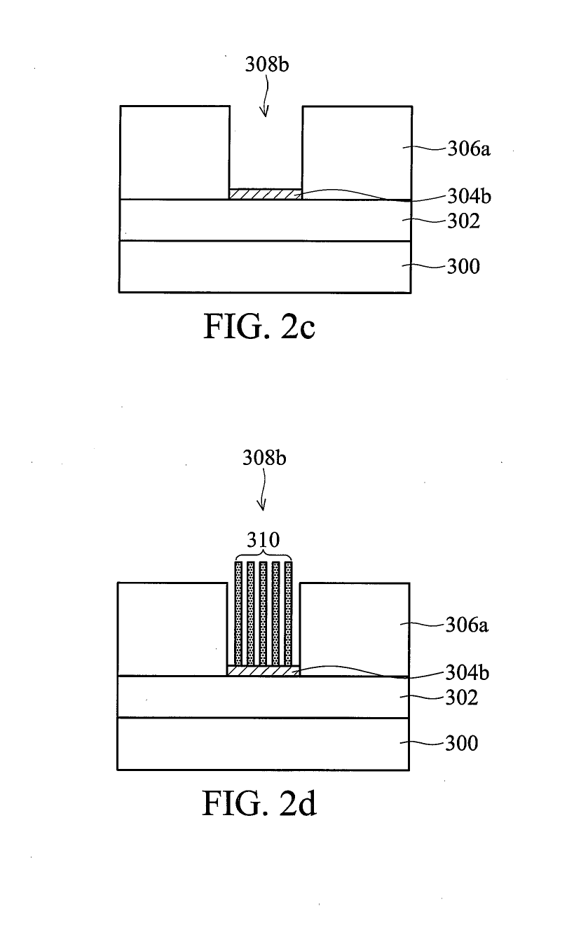

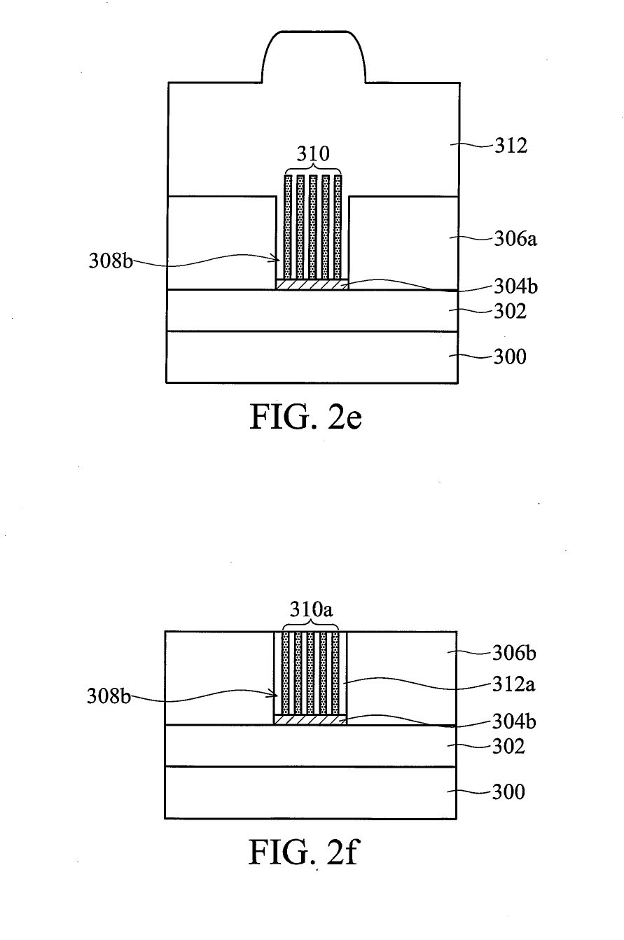

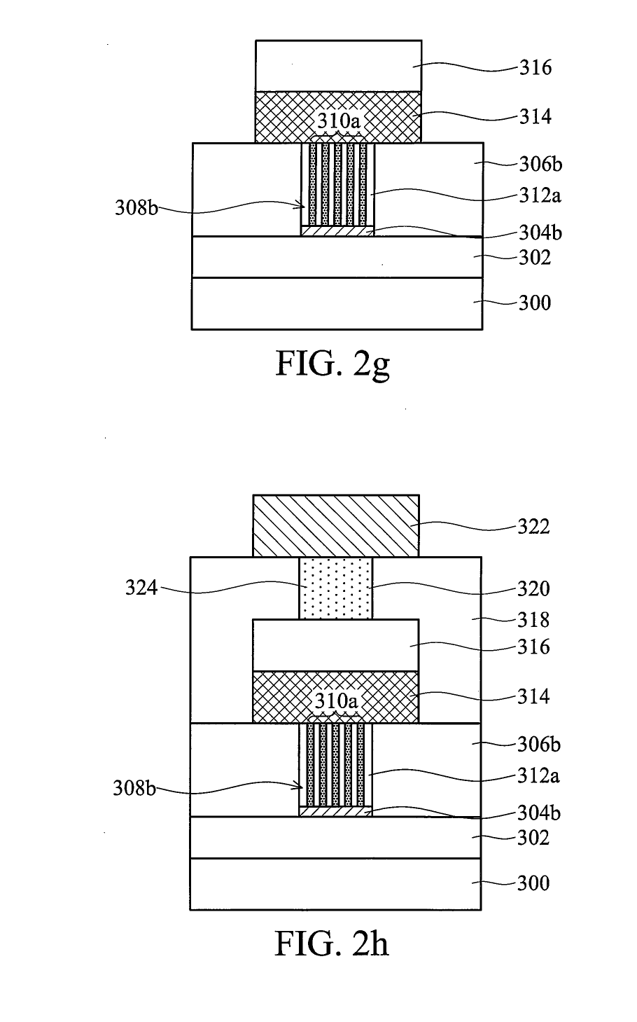

FIGS. 1a to 1h show cross sections of an exemplary embodiment of a phase change memory device of the invention. FIGS. 2a to 2h show cross sections of another exemplary embodiment of a phase change memory device of the invention. Wherever possible, the same reference numbers are used in the drawings and the descriptions of the same or like parts.

FIG. 1a illustrates a cross section of an exemplary embodiment of a phase change memory device of the invention. A substrate 300 is provided. The substrate 300 may comprise silicon. In alternative embodiments, SiGe, bulk semiconductor, strained semiconductor, compound semiconductor, silicon on insulator (SOI), and other commonly used semiconductor substrates can be used for the substrate 300. The substrate 300 may also comprise a substrate having transistors, for example, complementary metal oxide semiconductor (CMOS) transistors or bipolar junction transistors (BJT).

Next, a first conductive layer 302, serving as bottom electrode layer 302, is formed on the substrate 300 by a deposition process, such as, physical vapor deposition (PVD), sputtering, low pressure chemical vapor deposition (LPCVD), atomic layer chemical vapor deposition (ALD) or electroless plating. The first conductive layer 302 may comprise polycrystalline semiconductor material, amorphous semiconductor material, metal silicide, metal nitride, nitrided metal silicide, refractory metal silicide, refractory metal nitride, nitrided refractory metal silicide, conductive oxide or combinations thereof. The first conductive layer 302 may also comprise cobalt (Co), tantalum (Ta), nickel (Ni), titanium (Ti), tungsten (W), TiW, TaN refractory metals or composite metals.

Next, a catalytic material layer 304a is formed on the first conductive layer 302 by a deposition process, such as, physical vapor deposition (PVD), sputtering, low pressure chemical vapor deposition (LPCVD), atomic layer chemical vapor deposition (ALD) or electroless plating. The catalytic material layer 304a is used to catalyze a formation of a subsequence heating electrode. The catalytic material layer 304a may comprise iron (Fe), cobalt (Co), nickel (Ni) or the like.

Referring to FIG. 1b, a first dielectric layer 306a is formed on the catalytic material layer 304a by a thin film deposition process, such as, chemical vapor deposition (CVD). The first dielectric layer 306a may comprise silicon dioxide (SiO₂), silicon nitride (Si₃N₄) or the like. Next, referring to FIG. 1c, a patterned photoresist (not shown) is used to cover the first dielectric layer 306a and to define a position of an opening 308a. An anisotropic etching process is performed to remove the first dielectric layer 306a not covered by the patterned photoresist, until the catalytic material layer 304a is exposed. The patterned photoresist is then removed to form the opening 308a.

FIG. 1d illustrates a formation of heating electrodes 310. In one embodiment, the heating electrode 310 comprises a carbon nanotube (CNT). A plurality of heating electrodes 310, for example, a plurality of the carbon nanotubes, are grown on the catalytic material layer 304a in the opening 308a using hydrocarbon gas, for example, methane (CH₄) or carbon dioxide (CO₂), as a source gas for a chemical vapor deposition (CVD) process such as catalytic chemical vapor deposition. The heating electrodes 310 are grown vertically on the catalytic material layer 304a and parallel with each other.

Referring to FIG. 1e, a second dielectric layer 312 is formed on the first dielectric layer 306a, filling in the opening 308a and seams between the heating electrodes 310, and covering the heating electrode 310. The second dielectric layer 312 is formed by a thin film deposition process, such as, chemical vapor deposition (CVD). The second dielectric layer 312 may comprise silicon dioxide (SiO₂), silicon nitride (Si₃N₄) or the like. The first dielectric layer 306a and the second dielectric layer 312 may comprise the same materials. Alternatively, the first dielectric layer 306a and the second dielectric layer 312 may comprise different materials. Referring to FIG. If, a planarization process such as chemical mechanical polishing (CMP) is next performed to remove a portion of the first dielectric layer 306a, the second dielectric layer 312 and the heating electrode 310. After the planarization process is performed, the first dielectric layer 306b, the second dielectric layer 312a and the heating electrode 310a are formed, and the heating electrode 310a is exposed.

FIG. 1g illustrates formations of a phase change material layer 314 and a diffusion barrier layer 316. A phase change material layer (not shown) is blanketly formed by a deposition process, such as, physical vapor deposition (PVD), thermal evaporation, pulsed laser deposition or metal organic chemical vapor deposition (MOCVD). The phase change material layer (not shown) may comprise binary, ternary or tetra chalcogenide such as GaSb, GeTe, Ge—Sb—Te (GST) alloy, Ag—In—Sb—Te alloy or combinations thereof. Next, a diffusion barrier layer (not shown) may be formed optionally by a deposition process, such as, physical vapor deposition (PVD), thermal evaporation, pulsed laser deposition or metal organic chemical vapor deposition (MOCVD). The diffusion barrier layer is used to avoid metal diffusion into a phase change material layer and a dielectric layer. The diffusion barrier layer may comprise materials having higher conductivity, such as, WN, TiN, TaN, TiSiN or TaSiN. Next, a patterned photoresist (not shown) is used to cover the phase change material layer and the diffusion barrier layer. An anisotropic etching process is performed to remove the diffusion barrier layer not covered by the patterned photoresist. The patterned photoresist is then removed to form the phase change material layer 314 and the diffusion barrier layer 316. The phase change material layer 314 is electrically connected to the diffusion barrier layer 310a and covers the diffusion barrier layer 310a.

Referring to FIG. 1h, a third dielectric layer 318 is blanketly formed covering the phase change material layer 314, the diffusion barrier layer 316, and the first dielectric layer 306b, which is not covered by the phase change material layer 314. A planarization process such as chemical mechanical polishing (CMP) is next performed to remove an excess portion of the third dielectric layer 318 and planarize a surface of the third dielectric layer 318.

Next, a patterned photoresist (not shown) is used to cover the third dielectric layer 318 and define a position of a contact plug 320. An anisotropic etching process is performed to remove the third dielectric layer 318 not covered by the patterned photoresist, until the diffusion barrier layer 316 is exposed. The patterned photoresist is then removed to form a contact hole 324. Next, conductive materials such as tungsten (W) are filled into the contact hole 324. A planarization process such as chemical mechanical polishing (CMP) is next performed to form the contact plug 320 substantially coplanar with the third dielectric layer 318.

A conductive layer (not shown) is then formed on the third dielectric layer 318, covering the contact plug 320, wherein the conductive layer may be formed by a deposition process, such as, physical vapor deposition (PVD), thermal evaporation, pulsed laser deposition or metal organic chemical vapor deposition (MOCVD). Next, a patterned photoresist (not shown) is used to cover the conductive layer. An anisotropic etching process is performed to remove the conductive layer not covered by the patterned photoresist. The patterned photoresist is then removed to form a second conductive layer 322. The second conductive layer 322 is electrically connected to the phase change material layer 314 through the contact plug 320 and the diffusion barrier layer 316. The second conductive layer 322 may comprise tungsten (W), titanium (Ti), aluminum (Al), Al-alloy, copper (Cu), Cu-alloy or combinations thereof. Thus, an exemplary embodiment of a phase change memory device 100a of the invention is completely formed.

An exemplary embodiment of the phase change memory device 100a mainly comprises: a substrate 300; a first conductive layer 302 formed on the substrate 300; a catalytic material layer 304a formed on the first conductive layer 302; a first dielectric layer 306b formed on catalytic material layer 304a, having an opening 308a; a heating electrode 310a formed on the catalytic material layer 304a and in the opening 308a, and the heating electrode 310a is electrically connected to the first conductive layer 302, wherein the heating electrode 310a comprises a carbon nanotube (CNT); a second dielectric layer 312a filling in the opening 308a, adjacent to the heating electrode 310a and the first dielectric layer 306b; a phase change material layer 314 formed on the heating electrode 310a, covering the heating electrode 310a; a diffusion barrier layer 316 formed on the phase change material layer 314; a third dielectric layer 318 formed on the heating electrode 310a and the first dielectric layer 306b, adjacent to the phase change material layer 314; a contact plug 320 formed in the third dielectric layer 318, on the diffusion barrier layer 316; a second conductive layer 322 formed on the phase material layer 314, and electrically connected to the phase material layer 314 through the contact plug 320 and the diffusion barrier layer 316.

FIGS. 2a to 2h show cross sections of another exemplary embodiment of a phase change memory device of the invention. Note that the same elements in FIGS. 2a to 2h as shown in FIGS. 1a to 1h will not be repeated due to brevity.

FIG. 2a illustrates a formation of a first dielectric layer 306a. The first dielectric layer 306a is formed on the first conductive layer 302 by a thin film deposition process, such as, chemical vapor deposition (CVD). The first dielectric layer 306a may comprise silicon dioxide (SiO₂), silicon nitride (Si₃N₄) or the like. Next, referring to FIG. 2b, a patterned photoresist (not shown) is used to cover the first dielectric layer 306a and define a position of an opening 308b. An anisotropic etching process is then performed to remove the first dielectric layer 306a not covered by the patterned photoresist, until the first conductive layer 302 is exposed. The patterned photoresist is then removed to form the opening 308b.

Referring to FIG. 2c, a catalytic material layer 304b is formed on bottom of the opening 308b by a deposition process, such as, physical vapor deposition (PVD), sputtering, low pressure chemical vapor deposition (LPCVD), atomic layer chemical vapor deposition (ALD) or electroless plating. The catalytic material layer 304b is used to catalyze a formation of a subsequence heating electrode. The catalytic material layer 304b may comprise iron (Fe), cobalt (Co), nickel (Ni) or the like.

FIG. 2d illustrates a formation of heating electrodes 310. In one embodiment, the heating electrode 310 comprises a carbon nanotube (CNT). A plurality of the heating electrodes 310, for example, a plurality of carbon nanotubes, are grown on the catalytic material layer 304b in the opening 308b using hydrocarbon gas, for example, methane (CH₄) or carbon dioxide (CO₂), as a source gas for a chemical vapor deposition (CVD) process such as catalytic chemical vapor deposition. The heating electrodes 310 are grown vertically on the catalytic material layer 304b and parallel with each other.

Referring to FIG. 2e, a second dielectric layer 312 is formed on the first dielectric layer 306a, filling in the opening 308b, and covering the heating electrodes 310. The second dielectric layer 312 is formed by a thin film deposition process, such as, chemical vapor deposition (CVD). The second dielectric layer 312 may comprise silicon dioxide (SiO₂), silicon nitride (Si₃N₄) or the like. Referring to FIG. 2f, a planarization process such as chemical mechanical polishing (CMP) is next performed to remove portions of the first dielectric layer 306a, the second dielectric layer 312 and the heating electrode 310. After the planarization process is performed, the first dielectric layer 306b, the second dielectric layer 312a and the heating electrode 310a are formed, and the heating electrode 310a is exposed.

FIG. 2g illustrates formations of a phase change material layer 314 and a diffusion barrier layer 316. A phase change material layer is blanketly formed by a deposition process, such as, physical vapor deposition (PVD), thermal evaporation, pulsed laser deposition or metal organic chemical vapor deposition (MOCVD). The phase change material layer (not shown) may comprise binary, ternary or tetra chalcogenide such as GaSb, GeTe, Ge—Sb—Te (GST) alloy, Ag—In—Sb—Te alloy or combinations thereof. Next, a diffusion barrier layer (not shown) may be formed optionally by a deposition process, such as, physical vapor deposition (PVD), thermal evaporation, pulsed laser deposition or metal organic chemical vapor deposition (MOCVD). The diffusion barrier layer is used to avoid metal diffusion into a phase change material layer and a dielectric layer. The diffusion barrier layer may comprise materials having higher conductivity, such as, WN, TiN, TaN, TiSiN or TaSiN. Next, a patterned photoresist (not shown) is used to cover the phase change material layer and the diffusion barrier layer. An anisotropic etching process is performed to remove the diffusion barrier layer not covered by the patterned photoresist. The patterned photoresist is then removed to form the phase change material layer 314 and the diffusion barrier layer 316. The phase change material layer 314 is electrically connected to the diffusion barrier layer 310 and covers the diffusion barrier layer 310.

Referring to FIG. 2h, a third dielectric layer 318 is blanketly formed covering the phase change material layer 314, the diffusion barrier layer 316, and the first dielectric layer 306b, which is not covered by the phase change material layer 314. A planarization process such as chemical mechanical polishing (CMP) is next performed to remove an excess portion of the third dielectric layer 318 and planarize a surface of the third dielectric layer 318.

Next, a patterned photoresist (not shown) is used to cover the third dielectric layer 318 and define a position of a contact plug 320. An anisotropic etching process is performed to remove the third dielectric layer 318 not covered by the patterned photoresist, until the diffusion barrier layer 316 is exposed. The patterned photoresist is then removed to form a contact hole 324. Next, conductive materials such as tungsten (W) are filled into the contact hole 324. A planarization process such as chemical mechanical polishing (CMP) is next performed to form the contact plug 320 substantially coplanar with the third dielectric layer 318.

A conductive layer (not shown) is then formed on the third dielectric layer 318, covering the contact plug 320, wherein the conductive layer may be formed by a deposition process, such as, physical vapor deposition (PVD), thermal evaporation, pulsed laser deposition or metal organic chemical vapor deposition (MOCVD). Next, a patterned photoresist (not shown) is used to cover the conductive layer. An anisotropic etching process is performed to remove the conductive layer not covered by the patterned photoresist. The patterned photoresist is then removed to form a second conductive layer 322. The second conductive layer 322 is electrically connected to the contact plug 320 through the contact plug 320 and the diffusion barrier layer 316. The second conductive layer 322 may comprise tungsten (W), titanium (Ti), aluminum (Al), Al-alloy, copper (Cu), Cu-alloy or combinations thereof. Thus, another exemplary embodiment of a phase change memory device 100b of the invention is completely formed.

Another exemplary embodiment of the phase change memory device 100b mainly comprises: a substrate 300; a first conductive layer 302 formed on the substrate 300; a first dielectric layer 306b formed on the first conductive layer 302, having an opening 308b; a catalytic material layer 304b formed on the bottom of the opening 308b; a heating electrode 310a formed on the catalytic material layer 304a and in the opening 308b, and the heating electrode 310a is electrically connected to the first conductive layer 302, wherein the heating electrode 310a comprises a carbon nanotube (CNT); a second dielectric layer 312a filling in the opening 308a, adjacent to the heating electrode 310a and the first dielectric layer 306b; a phase change material layer 314 formed on the heating electrode 310a, covering the heating electrode 310a; a diffusion barrier layer 316 formed on the phase change material layer 314; a third dielectric layer 318 formed on the heating electrode 310a and the first dielectric layer 306b, adjacent to the phase change material layer 314; a contact plug 320 formed in the third dielectric layer 318, on the diffusion barrier layer 316; a second conductive layer 322 formed on the phase material layer 314, and electrically connected to the phase material layer 314 through the contact plug 320 and the diffusion barrier layer 316.

An exemplary embodiment of the phase change memory device uses carbon nanotubes (CNT) to replace a plug as a heating electrode of the conventional phase change memory device. A contact area between a phase change material layer and a heating electrode can be minimized and not limited by photolithography resolution. The carbon nanotubes (CNT) have some advantages of higher electromigration resistance, higher withstand current density (over 10⁹ A/cm²) and excellent thermal stability (carbon's melting point exceeds both at 3527° C ). Thus, requirements of device density and reliability improvement can be achieved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase change memory device, comprising:
a substrate;
a first conductive layer on the substrate;
a heating electrode on the first conductive layer, and electrically connected to the first conductive layer, wherein the heating electrode comprises a carbon nanotube (CNT);
a phase change material layer on the heating electrode, covering the heating electrode; and
a second conductive layer on the phase change material layer, and electrically connected to the phase change material layer.

2. The phase change memory device as claimed in claim 1, further comprising:
a catalytic material layer on the first conductive layer, connected to the heating electrode.

3. The phase change memory device as claimed in claim 2, further comprising:
a first dielectric layer between the first conductive layer and the phase change material layer, having an opening, wherein the heating electrode is in the opening, and the catalytic material layer is on the bottom of the opening; and
a second dielectric layer filling in the opening, adjacent to the heating electrode and the first dielectric layer.

4. The phase change memory device as claimed in claim 3, wherein the catalytic material layer is extended between the first conductive layer and the first dielectric layer.

5. The phase change memory device as claimed in claim 3, wherein the first dielectric layer and the second dielectric layer comprise the same materials.

6. The phase change memory device as claimed in claim 1, further comprising:
a diffusion barrier layer on the phase change material layer; and
a contact plug on the diffusion barrier layer, wherein the second conductive layer is electrically connected to the phase material layer through the contact plug and the diffusion barrier layer.

7. The phase change memory device as claimed in claim 1, further comprising:
a third dielectric layer between the heating electrode and the second conductive layer, adjacent to the phase change material layer.

8. The phase change memory device as claimed in claim 1, wherein the phase change material layer comprises GaSb, GeTe, Ge—Sb—Te (GST), Ag—In—Sb—Te or combinations thereof.

9. The phase change memory device as claimed in claim 1, wherein the first conductive layer comprises metal silicide, metal nitride, nitrided metal silicide, refractory metal silicide, refractory metal nitride, nitrided refractory metal silicide, polycrystalline semiconductor material, amorphous semiconductor material, conductive oxide or combinations thereof.

10. The phase change memory device as claimed in claim 1, wherein the second conductive layer comprises metal silicide, metal nitride, nitrided metal silicide, refractory metal silicide, refractory metal nitride, nitrided refractory metal silicide, polycrystalline semiconductor material, amorphous semiconductor material, conductive oxide or combinations thereof.

11. A method of fabricating a phase change memory device, comprising: providing a substrate having a first conductive layer thereon;
forming a heating electrode on the first conductive layer, and electrically connected to the first conductive layer, wherein the heating electrode comprises a carbon nanotube (CNT);
forming a phase change material layer on the heating electrode, covering the heating electrode; and
forming a second conductive layer on the phase change material layer, and electrically connected to the phase change material layer.

12. The method of fabricating the phase change memory device as claimed in claim 11, further comprising:
forming a catalytic material layer on the first conductive layer, connected to the heating electrode before forming the heating electrode.

13. The method of fabricating the phase change memory device as claimed in claim 12, further comprising:
forming a first dielectric layer on the first conductive layer, having an opening, wherein the catalytic material layer is on bottom of the opening;
forming a heating electrode in the opening;
forming a second dielectric layer on the first dielectric layer, filling in the opening and covering the heating electrode; and
performing a planarization process to remove a portion of the first dielectric layer, the second dielectric layer and the heating electrode, until the heating electrode is exposed before forming the heating electrode.

14. The method of fabricating the phase change memory device as claimed in claim 13, wherein the first and the second dielectric layers comprise the same materials

15. The method of fabricating the phase change memory device as claimed in claim 13, wherein the catalytic material layer is extended between the first conductive layer and the first dielectric layer

16. The method of fabricating the phase change memory device as claimed in claim 11, further comprising:
forming a diffusion barrier layer on the phase change material layer; and
forming a contact plug on the diffusion barrier layer, wherein the second conductive layer is electrically connected to the phase material layer through the contact plug and the diffusion barrier layer.

17. The method of fabricating the phase change memory device as claimed in claim 11, further comprising:
forming a third dielectric layer between the heating electrode and the second conductive layer, adjacent to the phase change material layer.

18. The method of fabricating the phase change memory device as claimed in claim 11, wherein the first conductive layer is formed by physical vapor deposition, (PVD), thermal evaporation, pulsed laser deposition or metal organic chemical vapor deposition (MOCVD).

19. The method of fabricating the phase change memory device as claimed in claim 11, wherein the second conductive layer is formed by physical vapor deposition, (PVD), thermal evaporation, pulsed laser deposition or metal organic chemical vapor deposition (MOCVD).
